(19) United States
(12) Patent Application Publication
(10) Pub. No.: US 2026/0211018 A1
(43) Pub. Date: Jul. 23, 2026

(54) MUTUAL INDUCTANCE IDENTIFICATION METHOD AND MUTUAL INDUCTANCE CALCULATION DEVICE USING SAME

(71) Applicant: Delta Electronics (Thailand) Public Company Limited, Samutprakarn (TH)

(72) Inventors: Yuan Shao, Shanghai (CN); Qing Jiang, Shanghai (CN); Yongkai Liao, Shanghai (CN)

(21) Appl. No.: 19/455,602

(22) Filed: Jan. 21, 2026

(30) Foreign Application Priority Data
Jan. 23, 2025 (CN) 202510114525.6

(51) Int. Cl. G01R 27/26

(52) U.S. Cl. CPC G01R 27/2611

(57) ABSTRACT

A mutual inductance identification method is provided. Firstly, a primary resonant current, a secondary resonant current and a secondary resonant voltage of the secondary circuit are sampled and filtered, and thus a first harmonic component and a second harmonic component in each of the primary resonant current, the secondary resonant current and the secondary resonant voltage are obtained. Then, the first harmonic component and the second harmonic component are modulated and demodulated. Consequently, the amplitude of the first harmonic component, the amplitude of the second harmonic component and the corresponding phase differences are obtained. Then, a mutual inductance parameter between the primary circuit and the secondary circuit is calculated according to the amplitude of the first harmonic component, the amplitude of the second harmonic component and the corresponding phase differences.

### CROSS-REFERENCE TO RELATED APPLICATION

This application claims priority to China Patent Application No. 202510114525.6, filed on Jan. 23, 2025, the entire contents of which are incorporated herein by reference for all purposes.

### FIELD OF THE INVENTION

The present disclosure relates to a mutual inductance technology, and more particularly to a mutual inductance identification method and a mutual inductance calculation device using the method.

### BACKGROUND OF THE INVENTION

An inductive power transfer (IPT) technology is developed according to the principle of electromagnetic induction. By using the IPT technology, the power transmission purpose can be achieved without physical contact. Since contact sparks, cumbersome plugging/unplugging procedures, power supply safety problems and other similar problems can be effectively solved, the IPT technology has attracted more and more attention. However, a large number of studies have shown that the output power and the transmission efficiency of the IPT technology are greatly affected by the coupling degree between the coupling coils. Consequently, it is important to accurately identify the mutual inductance parameters in the inductive power transfer systems or circuits.

For example, in accordance with the wireless charging technology of an electric vehicle (EV), the coupling coefficient mainly depends on the location where the vehicle is parked. In the actual application of inductive power transfer systems or circuits, it is usually difficult to avoid the misalignment of coupling coils (i.e. primary and secondary windings). Due to the misalignment, the mutual inductance parameters are instantly subjected to changes during operation. The changes of the mutual inductance parameters cause the changes of the coupling parameters and the energy transfer characteristics. Since the operating conditions and the transfer efficiency of the inductive power transmission system or circuit are affected, the transfer efficiency becomes unstable.

In order to overcome the drawbacks of the conventional technologies, it is important to provide a mutual inductance identification method and a mutual inductance calculation device using this method.

### SUMMARY OF THE INVENTION

The present disclosure provides a mutual inductance identification method and a mutual inductance calculation device for accurately identifying the mutual inductance parameters in the inductive power transfer systems or circuits. Due to the high stability of the proposed mutual inductance identification method and the mutual inductance calculation device, the operating conditions and the transfer efficiency of the inductive power transmission system or circuit are not obviously affected and the stability of the transfer efficiency will be enhanced.

In accordance with an aspect of the present disclosure, a mutual inductance identification method for a wireless power transmission system is provided. The wireless power transmission system includes a primary circuit, a resonant cavity and a secondary circuit. The mutual inductance identification method includes the following steps. Firstly, in a step (S1), a primary resonant current of the primary circuit is sampled, a secondary resonant current and a secondary resonant voltage of the secondary circuit are sampled, and the primary resonant current, the secondary resonant current and the secondary resonant voltage are filtered respectively. Consequently, a first harmonic component and a second harmonic component in each of the primary resonant current, the secondary resonant current and the secondary resonant voltage are obtained. The frequency of the first harmonic component and the frequency of the second harmonic component in each of the primary resonant current, the secondary resonant current and the secondary resonant voltage are different. In a step (S2), the first harmonic component and the second harmonic component in each of the primary resonant current, the secondary resonant current and the secondary resonant voltage are modulated and demodulated respectively. Consequently, an amplitude of the first harmonic component in each of the primary resonant current, the secondary resonant current and the secondary resonant voltage, an amplitude of the second harmonic component in each of the primary resonant current, the secondary resonant current and the secondary resonant voltage, a phase difference between the first harmonic component in the secondary resonant voltage and the first harmonic component in the secondary resonant current and a phase difference between the second harmonic component in the secondary resonant voltage and the second harmonic component in the secondary resonant current are obtained. In a step (S3), a mutual inductance parameter between the primary circuit and the secondary circuit is calculated according to the amplitude of the first harmonic component in each of the primary resonant current, the secondary resonant current and the secondary resonant voltage, the amplitude of the second harmonic component in each of the primary resonant current, the secondary resonant current and the secondary resonant voltage, the phase difference between the first harmonic component in the secondary resonant voltage and the first harmonic component in the secondary resonant current and the phase difference between the second harmonic component in the secondary resonant voltage and the second harmonic component in the secondary resonant current.

In accordance with another aspect of the present disclosure, a mutual inductance calculation device for a wireless power transmission system is provided. The wireless power transmission system includes a primary circuit, a resonant cavity and a secondary circuit. The mutual inductance calculation device includes a sampling circuit, a first filtering circuit, an analog switch, a second filtering circuit and a micro control unit. The sampling circuit is used for sampling a primary resonant current of the primary circuit and sampling a secondary resonant current and a secondary resonant voltage of the secondary circuit. After the primary resonant current, the secondary resonant current and the secondary resonant voltage are filtered respectively by the first filtering circuit, a first harmonic component and a second harmonic component in each of the primary resonant current, the secondary resonant current and the secondary resonant voltage are obtained. A frequency of the first harmonic component and a frequency of the second harmonic component in each of the primary resonant current, the secondary resonant current and the secondary resonant voltage are different. The analog switch is used for modulating the first harmonic component and the second harmonic component in each of the primary resonant current, the secondary resonant current and the secondary resonant voltage respectively. The modulated first harmonic component and the modulated second harmonic component in each of the primary resonant current, the secondary resonant current and the secondary resonant voltage are demodulated respectively by the second filtering circuit. The micro control unit obtains an amplitude of the first harmonic component in each of the primary resonant current, the secondary resonant current and the secondary resonant voltage and a phase difference between the first harmonic component in the secondary resonant voltage and the first harmonic component in the secondary resonant current according to the demodulated first harmonic component in each of the primary resonant current, the secondary resonant current and the secondary resonant voltage. The micro control unit obtains an amplitude of the second harmonic component in each of the primary resonant current, the secondary resonant current and the secondary resonant voltage, and a phase difference between the second harmonic component in the secondary resonant voltage and the second harmonic component in the secondary resonant current according to the demodulated second harmonic component in each of the primary resonant current, the secondary resonant current and the secondary resonant voltage. The micro control unit calculates a mutual inductance parameter between the primary circuit and the secondary circuit according to the amplitude of the first harmonic component in each of the primary resonant current, the secondary resonant current and the secondary resonant voltage, the amplitude of the second harmonic component in each of the primary resonant current, the secondary resonant current and the secondary resonant voltage, the phase difference between the first harmonic component in the secondary resonant voltage and the first harmonic component in the secondary resonant current and the phase difference between the second harmonic component in the secondary resonant voltage and the second harmonic component in the secondary resonant current.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a flowchart of a mutual inductance identification method according to an embodiment of the present disclosure;

FIG. 2 is a schematic circuit diagram illustrating the architecture of a wireless power transmission system using the mutual inductance identification method of FIG. 1;

FIG. 3 is a schematic circuit diagram illustrating an equivalent circuit diagram of the wireless power transmission system;

FIG. 4 is a schematic circuit block diagram illustrating a mutual inductance calculation device in the wireless power transmission system of FIG. 1;

FIG. 5 is a flowchart illustrating the detailed procedures of the step S2 in FIG. 1 by using a first method;

FIG. 6 is a flowchart illustrating sub-steps of the step S2 in the mutual inductance identification method of FIG. 1; and

FIG. 7 is a flowchart illustrating the detailed procedures of the step S2 in FIG. 1 by using a second method.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. For example, a first harmonic component could be termed a second harmonic component, a second harmonic component could be termed a first harmonic component. Besides, the “first” and “second” in first harmonic component and second harmonic component are used to express the different reference numerals, instead of expressing the frequency of harmonic components.

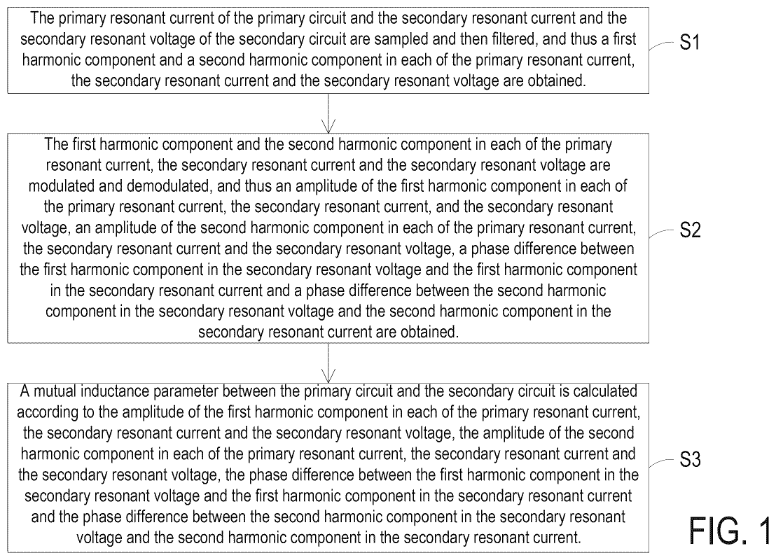

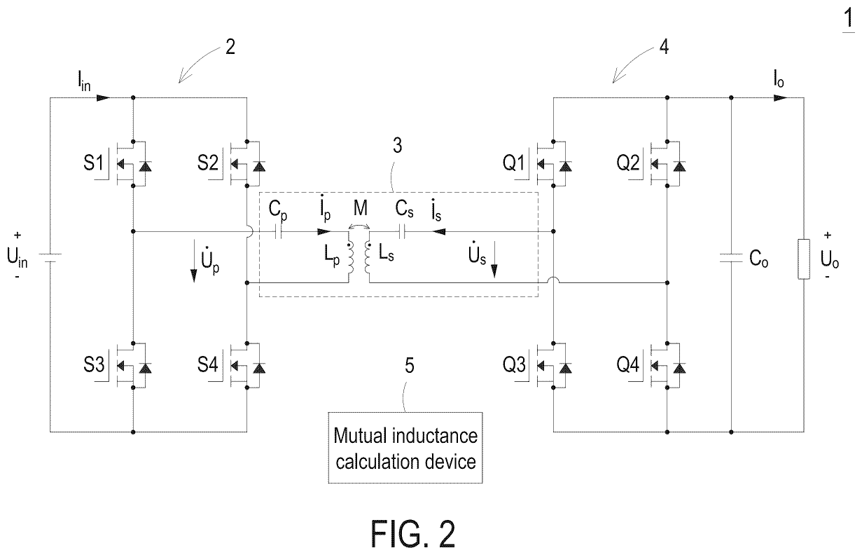

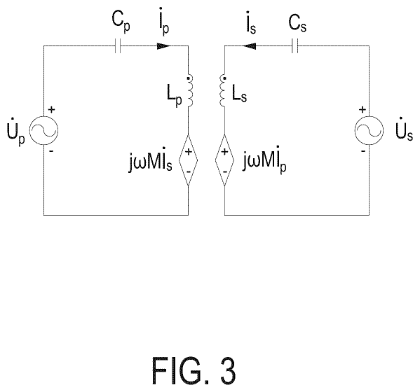

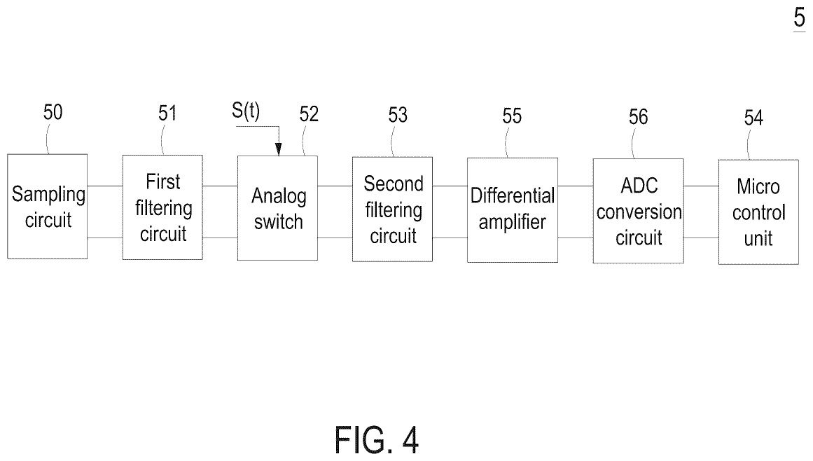

Please refer to FIGS. 1, 2, 3 and 4. FIG. 1 is a flowchart of a mutual inductance identification method according to an embodiment of the present disclosure. FIG. 2 is a schematic circuit diagram illustrating the architecture of a wireless power transmission system using the mutual inductance identification method of FIG. 1. FIG. 3 is a schematic circuit diagram illustrating an equivalent circuit diagram of the wireless power transmission system. FIG. 4 is a schematic circuit block diagram illustrating a mutual inductance calculation device in the wireless power transmission system of FIG. 1. The mutual inductance identification method can be applied to a mutual inductance calculation device 5 of a wireless power transmission system 1. The wireless power transmission system 1 further includes a primary circuit 2, a resonant cavity 3 and a secondary circuit 4.

The primary circuit 2 receives an input voltage Uᵢₙ and an input current Iᵢₙ. In addition, the input voltage Uᵢₙ and the input current Iᵢₙ are converted into a primary resonant voltage \dot{U}_{P} and a primary resonant current İ_{P} by the primary circuit 2. The resonant cavity 3 is electrically connected between the primary circuit 2 and the secondary circuit 4. In addition, the resonant cavity 3 includes a primary winding L_{P} and a secondary winding L_{S}. The primary winding L_{P} and the secondary winding L_{S} are electromagnetically coupled to each other. In addition, the primary winding L_{P} is electrically connected to the primary circuit 2 to receive the primary resonant voltage \dot{U}_{P} and the primary resonant current İ_{P}. The secondary winding L_{S} is electrically connected with the secondary circuit 4. According to the electromagnetic induction of the primary resonant voltage \dot{U}_{P} and the primary resonant current İ_{P}, the secondary winding L_{S} generates a secondary resonant voltage \dot{U}_{S} and a secondary resonant current İ_{S}. The secondary circuit 4 receives the secondary resonant voltage \dot{U}_{S} and the secondary resonant current İ_{S}. In addition, the secondary resonant voltage \dot{U}_{S} and the secondary resonant current İ_{S} are converted into an output voltage Uₒ and an output current Iₒ by the secondary circuit 4.

In an embodiment, the primary circuit 2 is a first bridge switch circuit with a full-bridge circuitry topology. The first bridge switch circuit includes a first bridge arm and a second bridge arm, which are connected with each other in parallel. The first bridge arm includes a first primary switch S1 and a third primary switch S3 connected in series. The second bridge arm includes a second primary switch S2 and a fourth primary switch S4. It is noted that the circuitry topology of the primary circuit 2 is not restricted to the full-bridge circuitry topology and can be any other appropriate inverter circuitry topology. For example, in some other embodiments, the primary circuit 2 has a half-bridge circuitry topology.

In an embodiment, the secondary circuit 4 is a second bridge switch circuit with a full-bridge circuitry topology. The secondary circuit 4 includes a third bridge arm and a fourth bridge arm, which are connected with each other in parallel. The third bridge arm includes a first secondary switch Q1 and a third secondary switch Q3. The fourth bridge arm includes a second secondary switch Q2 and a fourth secondary switch Q4. It is noted that the circuitry topology of the secondary circuit 4 is not restricted to the full-bridge circuitry topology and can be any other appropriate rectifier circuitry topology. For example, in some other embodiments, the secondary circuit 4 has a half-bridge circuitry topology, an uncontrolled circuitry topology, a semi-controlled circuitry topology or a fully-controlled circuitry topology.

The first primary switch S1, the second primary switch S2, the third primary switch S3 and the fourth primary switch S4 are Si MOSFET transistors, SiC MOSFET transistors, or the like. The first secondary switch Q1, the second secondary switch Q2, the third secondary switch Q3 and the fourth secondary switch Q4 are Si MOSFET transistors, SiC MOSFET transistors, power diodes, or the like.

In an embodiment, the resonant cavity 3 further includes a primary compensation capacitor C_{P} and a secondary compensation capacitor C_{S}. The primary compensation capacitor C_{P} is electrically connected between the primary circuit 2 and the primary winding L_{P}. The secondary compensation capacitor C_{S} is electrically connected between the secondary winding L_{S} and the secondary circuit 4. In some embodiments, the wireless power transmission system 1 further includes an output capacitor Cₒ. The output capacitor Cₒ is connected with the fourth bridge arm in parallel.

The mutual inductance calculation device 5 is electrically connected with the primary circuit 2, the resonant cavity 3 and the secondary circuit 4. The mutual inductance calculation device 5 can measure voltage parameters and/or current parameters in the primary circuit 2, the resonant cavity 3 and the secondary circuit 4. For example, the mutual inductance calculation device 5 measures the primary resonant voltage \dot{U}_{P}, the primary resonant current Ī_{P}, the secondary resonant voltage \dot{U}_{S} and the secondary resonant current İ_{S} and calculates the mutual inductance parameter between the primary circuit 2 and the secondary circuit 4 according to the measurement results. Specifically, the mutual inductance calculation device 5 calculates the mutual inductance parameter between the primary winding L_{P} and the secondary winding L_{S} according to the measurement results.

According to the equivalent circuits of the primary circuit 2 and the secondary circuit 4 of the wireless power transmission system shown in FIG. 3 and the Kirchhoff's voltage formula, the following formulas (1) and (2) are obtained:

$$\{ \begin{matrix}\dot{{U}_{P}} = ( j ω {L}_{P} + \frac{1}{j ω {C}_{P}} ) \dot{{I}_{P}} + j ω M \dot{{I}_{s}} & ( 1 ) \\ \dot{{U}_{S}} = ( j ω {L}_{S} + \frac{1}{j ω {C}_{S}} ) \dot{{I}_{S}} + j ω M \dot{{I}_{P}} & ( 2 )\end{matrix}$$

In the above formulas, \dot{U}_{P} is the primary resonant voltage, L_{P} is the self-inductance of the primary winding, C_{P} is the capacitance of the primary compensation capacitor,

$${\dot{I}}_{P}$$

is the primary resonant current, ω is the angular frequency, M is the mutual inductance parameter between the primary winding L_{P} and the secondary winding L_{S} (i.e., between the primary circuit 2 and the secondary circuit 4), \dot{U}_{S} is the secondary resonant voltage, L_{S} is the self-inductance of the secondary winding, C_{S} is the capacitance of the secondary compensation capacitor,

$${\dot{I}}_{S}$$

is the secondary resonant current.

The mutual inductance parameter M, the self-inductance of the primary winding L_{P} and the self-inductance of the secondary winding L_{S} are greatly affected by air gap, offset or other factors. These values have large fluctuation ranges and are usually regarded as unknown quantities. After the resonance parameters are determined, the capacitance value of the primary compensation capacitor C_{P} and the capacitance value of the secondary compensation capacitor C_{S} are hardly subjected to changes because they are usually made of high-stability material. In other words, the capacitance value of the primary compensation capacitor C_{P} and the capacitance value of the secondary compensation capacitor C_{S} are usually regarded as known quantities.

The primary resonant voltage \dot{U}_{P}, the secondary resonant voltage \dot{U}_{S}, the primary resonant current

$${\dot{I}}_{P}$$

and the secondary resonant current

$${\dot{I}}_{S}$$

can be measured by the mutual inductance calculation device 5. In order to calculate the three unknown quantities M, L_{P} and L_{S} using the formulas (1) and (2), the working frequency of the wireless power transmission system 1 can be altered. The operating frequency of the wireless power transmission system 1 can be changed to increase the number of formulas according to the formulas (1) and (2). For example, two different frequency components (e.g., different frequencies f1 and f2) can be selected. At the frequency f1, the formulas (1) and (2) can be extended to derive the following formulas (3) and (4). At the frequency f2, the formulas (1) and (2) can be extended to derive the following formulas (5) and (6).

$$\dot{{U}_{P 1}} = ( j {ω}_{1} {L}_{P} + \frac{1}{j {ω}_{1} {C}_{P}} ) \dot{{I}_{P 1}} + j {ω}_{1} M \dot{{I}_{S 1}} \qquad ( 3 )$$

$$\dot{{U}_{S 1}} = ( j {ω}_{1} {L}_{S} + \frac{1}{j {ω}_{1} {C}_{S}} ) \dot{{I}_{S 1}} + j {ω}_{1} M \dot{{I}_{P 1}} \qquad ( 4 )$$

$$\dot{{U}_{P 2}} = ( j {ω}_{2} {L}_{P} + \frac{1}{j {ω}_{2} {C}_{P}} ) \dot{{I}_{P 2}} + j {ω}_{2} M \dot{{I}_{S 2}} \qquad ( 5 )$$

$$\dot{{U}_{S 2}} = ( j {ω}_{2} {L}_{S} + \frac{1}{j {ω}_{2} {C}_{S}} ) \dot{{I}_{S 2}} + j {ω}_{2} M \dot{{I}_{P 2}} \qquad ( 6 )$$

Since the amplitudes of the primary resonant voltages

$${\dot{U}}_{P 1}$$

and

$${\dot{U}}_{P 2}$$

are large in practical applications are difficult to measure directly, the formulas (4) and (6) are used to calculate the mutual inductance parameter M between the primary winding L_{P} and the secondary winding L_{S}. Furthermore, the formulas (4) and (6) can be integrated as the following formula (7):

$$\dot{{U}_{S ι}} = ( j {ω}_{i} {L}_{S} + \frac{1}{j {ω}_{i} {C}_{S}} ) \dot{{I}_{S ι}} + j {ω}_{i} M \dot{{I}_{P ι}} \qquad ( 7 )$$

In the above formula, \dot{U}_{S}, is the i-th harmonic component in the secondary resonant voltage \dot{U}_{S},

$${\dot{I}}_{P ι}$$

is the i-th harmonic component in the primary resonant current

$${\dot{I}}_{P} , {\dot{I}}_{S ι}$$

is the i-th harmonic component in the secondary resonant current

$${\dot{I}}_{S} ,$$

and ωᵢ is the angular frequency at the i-th harmonic component.

Since some parameters in the formulas (4) and (6) contain AC components and both amplitude and phase need to be considered when the AC components are measured, the formulas (4) and (6) can be converted into the following equations (8) and (9):

$${ω}_{1} M \vert \dot{{I}_{P 1}} \vert = \sqrt{{( ( {ω}_{1} {L}_{S} - \frac{1}{{ω}_{1} {C}_{S}} ) \vert \dot{{I}_{S 1}} \vert - \vert \dot{{U}_{S 1}} \vert sin {θ}_{1} )}^{2} + {( \vert \dot{{U}_{S 1}} \vert cos {θ}_{1} )}^{2}} \qquad ( 8 )$$

$${ω}_{2} M \vert \dot{{I}_{P 2}} \vert = \sqrt{{( ( {ω}_{2} {L}_{S} - \frac{1}{{ω}_{2} {C}_{S}} ) \vert \dot{{I}_{S 2}} \vert - \vert \dot{{U}_{S 2}} \vert sin {θ}_{2} )}^{2} + {( \vert \dot{{U}_{S 2}} \vert cos {θ}_{2} )}^{2}} \qquad ( 9 )$$

In the above formula, θ₁ is the phase difference between the secondary resonant voltage

$$\dot{{U}_{S 1}}$$

and the secondary resonant current İ_{S1} when the working frequency of the wireless power transmission system 1 is the frequency f₁, and θ₂ is the phase difference between the secondary resonant voltage

$$\dot{{U}_{S 2}}$$

and the secondary resonant current İ_{S2} when the working frequency of the wireless power transmission system 1 is the frequency f₂.

As mentioned above, when the working frequency of the wireless power transmission system 1 is the frequency f₁, the amplitude of the primary resonant current İ_{P} is

$$\vert \dot{{I}_{P 1}} \vert ,$$

the amplitude of the secondary resonant current İ_{S} is

$$\vert \dot{{I}_{S 1}} \vert ,$$

the amplitude of the secondary resonant voltage \dot{U}_{S} is

$$\vert \dot{{U}_{S 1}} \vert ,$$

and the phase difference between the secondary resonant voltage \dot{U}_{S} and the secondary resonant current

$${\dot{I}}_{S}$$

is θ₁. Similarly, when the working frequency of the wireless power transmission system 1 is the frequency f₂, the amplitude of the primary resonant current İ_{P} is

$$\vert \dot{{I}_{P 2}} \vert ,$$

the amplitude of the primary resonant current

$${\dot{I}}_{S} is \vert {\dot{I}}_{S 2} \vert ,$$

the amplitude of the secondary resonant voltage \dot{U}_{S} is

$$\vert {\dot{U}}_{S 2} \vert ,$$

and the phase difference between the secondary resonant voltage \dot{U}_{S} and the secondary resonant current

$${\dot{I}}_{S}$$

is θ₂. According to these values and known capacitance value of the secondary compensation capacitor C_{S}, the mutual inductance parameter M between the primary winding L_{P} and the secondary winding L_{S} can be calculated. By using the two formulas (8) and (9), the two unknown parameters, namely the mutual inductance parameter M and the self-inductance of the secondary winding L_{S} can be determined.

Since the primary circuit 2 is an inverter, its output voltage is a square wave signal. In combination with the certain filtering characteristics of the resonant cavity 3, the primary resonant current İ_{P} and the secondary resonant current

$${\dot{I}}_{S}$$

are mixing signals dominated by the fundamental wave, and the secondary resonant voltage \dot{U}_{S} is a square wave signal. The square wave signal contains sinusoidal wave components of various frequencies. Consequently, a filter can be used to extract the sinusoidal wave components of two frequencies to achieve control of multiple frequencies. After the square wave signal is filtered, two frequency signals (sinusoidal waves) are obtained. Then, the analog switch is used to modulate the two frequency signals respectively, and the output signal from the analog switch is low-pass filtered and converted by an analog-to-digital converter (i.e., coherent demodulation). Consequently, the corresponding amplitudes and phases of the sinusoidal wave components of the two frequencies are calculated. Hereinafter, two solutions for the amplitudes and phases of the sine wave components of the corresponding frequencies will be introduced in detail.

From the mathematic formulas, the following general mathematic formulas (10) and (11) can be deduced from the equations (8) and (9):

$${ω}_{i} M \vert {\dot{I}}_{P ι} \vert = \sqrt{{( ( {ω}_{i} {L}_{S} - \frac{1}{{ω}_{i} {C}_{S}} ) \vert {\dot{I}}_{S ι} \vert - \vert {\dot{U}}_{S ι} \vert sin {θ}_{i} )}^{2} + {( \vert {\dot{U}}_{S ι} \vert cos {θ}_{i} )}^{2}} \qquad ( 10 )$$

$${θ}_{i} = {φ}_{{U}_{Si}} - {φ}_{{I}_{Si}} \qquad ( 11 )$$

In the above formulas,

$${\dot{U}}_{S ι}$$

is the i-th harmonic component in the secondary resonant voltage \dot{U}_{S},

$${\dot{I}}_{S ι}$$

is the i-th harmonic component in the secondary resonant current

$$\dot{{I}_{S}} , \dot{{I}_{P ι}}$$

is the i-th harmonic component in the primary resonant current İ_{P}, ωᵢ is the angular frequency at the i-th harmonic component, θᵢ is the phase difference between the i-th harmonic component in the secondary resonant voltage \dot{U}_{S} and the i-th harmonic component in the secondary resonant current İ_{S}, φ_{U}_{_{Si}} is the phase of the i-th harmonic component in the secondary resonant voltage \dot{U}_{S}, and φ_{I}_{_{Si}} is the i-th harmonic component in the secondary resonant current İ_{S}.

In FIG. 4, the circuit block diagram of the mutual inductance calculation device 5 is shown. As shown in FIG. 4, the mutual inductance calculation device 5 includes a sampling circuit 50, a first filtering circuit 51, an analog switch 52, a second filtering circuit 53 and a micro control unit 54.

The sampling circuit 50 is electrically connected with the primary circuit 2 and the secondary circuit 4 to sample the primary resonant current İ_{P} of the primary circuit 2 and sample the secondary resonant current İ_{S} and the secondary resonant voltage \dot{U}_{S} of the secondary circuit 4.

After the primary resonant current İ_{P}, the secondary resonant current

$$\dot{{I}_{S}}$$

and the secondary resonant voltage \dot{U}_{S} are sampled by the sampling circuit 50 and then filtered by the first filtering circuit 51 respectively, the first harmonic component and the second harmonic component in each of the primary resonant current İ_{P}, the secondary resonant current

$$\dot{{I}_{S}}$$

and the secondary resonant voltage \dot{U}_{S} are obtained. The frequency of the first harmonic component and the frequency of the second harmonic component in each of the primary resonant current İ_{P}, the secondary resonant current

$$\dot{{I}_{S}}$$

and the secondary resonant voltage \dot{U}_{S} are different. As mentioned above, the formula (2) is extended to the formulas (4) and (6) respectively. The frequency of the first harmonic component in the primary resonant current İ_{P}, the frequency of the first harmonic component in the secondary resonant current

$$\dot{{I}_{S}}$$

and the frequency of the first harmonic component in the secondary resonant voltage \dot{U}_{S} are identical. The frequency of the second harmonic component in the primary resonant current İ_{P}, the frequency of the second harmonic component in the secondary resonant current

$$\dot{{I}_{S}}$$

and the frequency of the second harmonic component in the secondary resonant voltage \dot{U}_{S} are identical. The frequency of the first harmonic component and the frequency of the corresponding second harmonic component are different. The first filtering circuit 51 may include an active high/low pass filter circuit. In order to ensure performance, the operational amplifier used in the first filtering circuit 51 should have a high gain bandwidth product.

The analog switch 52 modulates the first harmonic component and the second harmonic component in each of the primary resonant current İ_{P}, the secondary resonant current

$$\dot{{I}_{S}}$$

and the secondary resonant voltage \dot{U}_{S} according to the received carrier signal respectively. The modulated first harmonic component and the modulated second harmonic component in each of the primary resonant current İ_{P}, the secondary resonant current

$$\dot{{I}_{S}}$$

and the secondary resonant voltage \dot{U}_{S} are demodulated by the second filtering circuit 53 respectively. The modulation and demodulation methods will be described in detail later. In some embodiments, the second filtering circuit 53 includes a low-pass filtering circuit with a lower cut-off frequency, and the operational amplifier in the second filtering circuit 53 has a lower gain-bandwidth product.

According to the demodulated first harmonic component in each of the primary resonant current

$$\dot{{I}_{P}} ,$$

the secondary resonant current

$$\dot{{I}_{S}}$$

and the secondary resonant voltage \dot{U}_{S}, the micro control unit 54 obtains the amplitude of the first harmonic component in the primary resonant current İ_{P}, the amplitude of the first harmonic component in the secondary resonant current

$$\dot{{I}_{S}} ,$$

the amplitude of the first harmonic component in the secondary resonant voltage \dot{U}_{S} and the phase difference between the first harmonic component in the secondary resonant voltage \dot{U}_{S} and the first harmonic component in the secondary resonant current

$$\dot{{I}_{S}} .$$

According to the demodulated second harmonic component in each of the primary resonant current

$$\dot{{I}_{P}} ,$$

the secondary resonant current

$$\dot{{I}_{S}}$$

and the secondary resonant voltage \dot{U}_{S}, the micro control unit 54 obtains the amplitude of the second harmonic component in the primary resonant current

$$\dot{{I}_{P}} ,$$

the amplitude of the second harmonic component in the secondary resonant current

$$\dot{{I}_{S}} ,$$

the amplitude of the second harmonic component in the secondary resonant voltage \dot{U}_{S} and the phase difference between the second harmonic component in the secondary resonant voltage \dot{U}_{S} and the second harmonic component in the secondary resonant current

$$\dot{{I}_{S}} .$$

Furthermore, the micro control unit 54 calculates the mutual inductance parameter between the primary circuit 2 and the secondary circuit 4 according to the amplitude of the first harmonic component in the primary resonant current

$$\dot{{I}_{P}} ,$$

the amplitude of the first harmonic component in the secondary resonant current

$$\dot{{I}_{S}} ,$$

the amplitude of the first harmonic component in the secondary resonant voltage \dot{U}_{S}, the amplitude of the second harmonic component in the primary resonant current

$$\dot{{I}_{P}} ,$$

the amplitude of the second harmonic component in the secondary resonant current

$$\dot{{I}_{S}} ,$$

the amplitude of the second harmonic component in the secondary resonant voltage \dot{U}_{S}, the phase difference between the first harmonic component in the secondary resonant voltage \dot{U}_{S} and the first harmonic component in the secondary resonant current

$$\dot{{I}_{S}}$$

and the phase difference between the second harmonic component in the secondary resonant voltage \dot{U}_{S} and the second harmonic component in the secondary resonant current İ_{S}.

The first method of calculating the amplitude and phase difference is obtained according to the two DC components of the first harmonic component and the two DC components of the second harmonic component in each of the primary resonant current İ_{P}, the secondary resonant current

$$\dot{{I}_{S}}$$

and the secondary resonant voltage \dot{U}_{S}.

After the modulated first harmonic component and the modulated second harmonic component in each of the primary resonant current

$$\dot{{I}_{P}} ,$$

the secondary resonant current

$$\dot{{I}_{S}}$$

and the secondary resonant voltage \dot{U}_{S} are demodulated by the second filtering circuit 53 respectively, the two DC components of the first harmonic component and the two DC components of the second harmonic component in each of the primary resonant current

$$\dot{{I}_{P}} ,$$

and the secondary resonant current

$$\dot{{I}_{S}}$$

and the secondary resonant voltage \dot{U}_{S} are obtained. That is, the two DC components of the first harmonic component in the primary resonant current

$${\dot{I}}_{P} ,$$

and Two DC components of the second harmonic component in the primary resonant current

$$\dot{{I}_{P}} ,$$

the two DC components of the first harmonic component in the secondary resonant current

$$\dot{{I}_{S}} ,$$

the two DC components of the second harmonic component in the secondary resonant current

$$\dot{{I}_{S}} ,$$

the two DC components of the first harmonic component in the secondary resonant voltage \dot{U}_{S} and the two DC components of the second harmonic component in the secondary resonant voltage \dot{U}_{S} are obtained.

The micro control unit 54 calculates the amplitude and the phase of the first harmonic component in the primary resonant current İ_{P} according to the two DC components of the first harmonic component in the primary resonant current

$${\dot{I}}_{P} ,$$

and the micro control unit 54 calculates the amplitude and the phase of the second harmonic component in the primary resonant current İ_{P} according to the two DC components of the second harmonic component in the primary resonant current

$${\dot{I}}_{P} .$$

Similarly, the micro control unit 54 calculates the amplitude and the phase of the first harmonic component in the secondary resonant current

$${\dot{I}}_{S}$$

according to the two DC components of the first harmonic component in the secondary resonant current

$${\dot{I}}_{S} ,$$

and the micro control unit 54 calculates the amplitude and the phase of the second harmonic component in the secondary resonant current

$${\dot{I}}_{S}$$

according to the two DC components of the second harmonic component in the secondary resonant current

$${\dot{I}}_{S} .$$

Similarly, the micro control unit 54 calculates the amplitude and the phase of the first harmonic component in the secondary resonant voltage \dot{U}_{S} according to the two DC components of the first harmonic component in the secondary resonant voltage \dot{U}_{S}, and the micro control unit 54 calculates the amplitude and the phase of the second harmonic component in the secondary resonant voltage \dot{U}_{S} according to the two DC components of the second harmonic component in the secondary resonant voltage \dot{U}_{S}.

The micro control unit 54 calculates the phase difference between the phase of the first harmonic component in the secondary resonant voltage \dot{U}_{S} and the phase of the first harmonic component in the secondary resonant current

$${\dot{I}}_{S}$$

according to the phase of the first harmonic component in the secondary resonant voltage \dot{U}_{S} and the phase of the first harmonic component in the secondary resonant current

$${\dot{I}}_{S} .$$

Similarly, the micro control unit 54 calculates the phase difference between the phase of the second harmonic component in the secondary resonant voltage \dot{U}_{S} and the phase of the second harmonic component in the secondary resonant current

$${\dot{I}}_{S}$$

according to the phase of the second harmonic component in the secondary resonant voltage \dot{U}_{S} and the phase of the second harmonic component in the secondary resonant current

$${\dot{I}}_{S} .$$

Afterwards, the micro control unit 54 uses the formulas (8) and (9) to calculate the mutual inductance parameter between the primary circuit 2 and the secondary circuit 4 according to the amplitude of the first harmonic component in the primary resonant current

$${\dot{I}}_{P} ,$$

the amplitude of the second harmonic component in the primary resonant current

$${\dot{I}}_{P} ,$$

the amplitude or the first harmonic component in the secondary resonant current

$${\dot{I}}_{S} ,$$

the amplitude of the second harmonic component in the secondary resonant current

$${\dot{I}}_{S} ,$$

the amplitude of the first harmonic component in the secondary resonant voltage \dot{U}_{S}, the amplitude of the second harmonic component in the secondary resonant voltage \dot{U}_{S}, the phase difference between the first harmonic component in the secondary resonant voltage \dot{U}_{S} and the first harmonic component in the secondary resonant current

$${\dot{I}}_{S}$$

and the phase difference between the second harmonic component in the secondary resonant voltage \dot{U}_{S} and the second harmonic component in the secondary resonant current

$${\dot{I}}_{S} .$$

In an embodiment, the mutual inductance calculation device 5 further includes a differential amplifier 55 and an ADC conversion circuit 56. By the differential amplifier 55, the amplitudes of the two DC components of the first harmonic component in the primary resonant current

$${\dot{I}}_{P} ,$$

the amplitudes of the two DC components of the second harmonic component in the primary resonant current İ_{P}, the amplitudes of the two DC components of the first harmonic component in the secondary resonant current

$${\dot{I}}_{S} ,$$

the amplitudes of the two DC components of the second harmonic component in the secondary resonant current

$${\dot{I}}_{S} ,$$

the amplitudes of the two DC components of the first harmonic component in the secondary resonant voltage \dot{U}_{S} and the amplitudes of the two DC components of the second harmonic component in the secondary resonant voltage \dot{U}_{S} from the second filtering circuit 53 are adjusted. After the amplitudes are adjusted, the two DC components of the first harmonic component in the primary resonant current

$$\dot{{I}_{P}} ,$$

the two DC components of the second harmonic component in the primary resonant current

$$\dot{{I}_{P}} ,$$

the two DC components of the first harmonic component in the secondary resonant current

$$\dot{{I}_{S}} ,$$

the two DC components of the second harmonic component in the secondary resonant current

$$\dot{{I}_{S}} ,$$

the two DC components of the first harmonic component in the secondary resonant voltage \dot{U}_{S} and the two DC components of the second harmonic component in the secondary resonant voltage \dot{U}_{S} are subjected to analog/digital conversion by the ADC conversion circuit 56. The conversion results are transmitted to the micro control unit 54. According to the conversion results, the micro control unit 54 calculates the amplitude and the phase of the first harmonic component in the primary resonant current

$$\dot{{I}_{P}} ,$$

the amplitude and the phase of the second harmonic component in the primary resonant current

$$\dot{{I}_{P}} ,$$

the amplitude and the phase of the first harmonic component in the secondary resonant current

$$\dot{{I}_{S}} ,$$

the amplitude and the phase of the second harmonic component in the secondary resonant current

$$\dot{{I}_{S}} ,$$

the amplitude and the phase of the first harmonic component in the secondary resonant voltage \dot{U}_{S} and the amplitude and the phase of the second harmonic component in the secondary resonant voltage \dot{U}_{S}. In addition, the micro control unit 54 calculates the mutual inductance parameter between the primary circuit 2 and the secondary circuit 4 according to the amplitudes and the phases of the first harmonic component and the second harmonic component in each of the primary resonant current

$$\dot{{I}_{P}} ,$$

the secondary resonant current

$$\dot{{I}_{S}}$$

and the secondary resonant voltage \dot{U}_{S}.

As shown in FIG. 1, the mutual inductance identification method includes the following steps.

In a step S1, the primary resonant current

$$\dot{{I}_{P}}$$

of the primary circuit 2 and the secondary resonant current

$$\dot{{I}_{S}}$$

and the secondary resonant voltage \dot{U}_{S} of the secondary circuit 4 are sampled by the sampling circuit 50, and the primary resonant current

$$\dot{{I}_{P}} ,$$

the secondary resonant current

$$\dot{{I}_{S}}$$

and the secondary resonant voltage \dot{U}_{S} are filtered by the first filtering circuit 51 respectively. Consequently, the first harmonic component and the second harmonic component in each of the primary resonant current

$$\dot{{I}_{P}} ,$$

the secondary resonant current

$$\dot{{I}_{S}}$$

and the secondary resonant voltage \dot{U}_{S} are obtained.

In a step S2, the first harmonic component and the second harmonic component in each of the primary resonant current

$$\dot{{I}_{S}}$$

the secondary resonant current

$$\dot{{I}_{P}} ,$$

and the secondary resonant voltage \dot{U}_{S} are modulated by the analog switch 52 respectively and then demodulated by the second filtering circuit 53 respectively. According to the demodulated first harmonic component in each of the primary resonant

$$\dot{{I}_{S}}$$

the secondary resonant current

$$\dot{{I}_{P}} ,$$

and the secondary resonant voltage \dot{U}_{S}, the micro control unit 54 obtains the amplitude of the first harmonic component in the primary resonant current

$$\dot{{I}_{P}} ,$$

the amplitude or the first harmonic component in the secondary resonant current

$$\dot{{I}_{S}} ,$$

the amplitude of the first harmonic component in the secondary resonant voltage \dot{U}_{S} and the phase difference between the first harmonic component in the secondary resonant voltage \dot{U}_{S} and the first harmonic component in the secondary resonant current

$$\dot{{I}_{S}} .$$

According to the demodulated second harmonic component in each of the primary resonant current

$$\dot{{I}_{P}} ,$$

the secondary resonant current

$$\dot{{I}_{S}}$$

and the secondary resonant voltage \dot{U}_{S}, the micro control unit 54 obtains the amplitude of the second harmonic component in the primary resonant current

$$\dot{{I}_{P}} ,$$

the amplitude of the second harmonic component in the secondary resonant current

$$\dot{{I}_{S}} ,$$

the amplitude of the second harmonic component in the secondary resonant voltage \dot{U}_{S} and the phase difference between the second harmonic component in the secondary resonant voltage \dot{U}_{S} and the second harmonic component in the secondary resonant current

$$\dot{{I}_{S}} ,$$

In a step S3, the micro control unit 54 calculates the mutual inductance parameter between the primary circuit 2 and the secondary circuit 4 according to the amplitude of the first harmonic component in each of the primary resonant current

$$\dot{{I}_{P}} ,$$

the secondary resonant current İ_{S} and the secondary resonant voltage

$$\dot{{U}_{S}} ,$$

the amplitude of the second harmonic component in each of the primary resonant current

$${\dot{I}}_{P} ,$$

the secondary resonant current İ_{S} and the secondary resonant voltage \dot{U}_{S}, the phase difference between the first harmonic component in the secondary resonant voltage \dot{U}_{S} and the first harmonic component in the secondary resonant current

$${\dot{I}}_{S}$$

and the phase difference between the second harmonic component in the secondary resonant voltage \dot{U}_{S} and the second harmonic component in the secondary resonant current

$${\dot{I}}_{S}$$

Generally, the higher-order harmonic components require more complex circuit topologies and more expensive sampling circuits and filtering circuits for sampling and processing signals. For increasing the performance, in some embodiments, the first harmonic component and the second harmonic component described in the step S1 are harmonic components with frequencies below the fifth order. In this embodiment, the first harmonic component is a fundamental component, and the second harmonic component is a third harmonic component. The frequency of the first harmonic component in the primary resonant current

$${\dot{I}}_{P} ,$$

the frequency of the first harmonic component in the secondary resonant current

$${\dot{I}}_{S}$$

and the frequency of the first harmonic component in the secondary resonant voltage \dot{U}_{S} are all equal. The frequency of the second harmonic component in the primary resonant current

$${\dot{I}}_{P} ,$$

the frequency of the second harmonic component in the secondary resonant current

$${\dot{I}}_{S}$$

and the frequency of the second harmonic component in the secondary resonant voltage \dot{U}_{S} are all equal. The frequency of the first harmonic component and the frequency of the second harmonic component in each of the primary resonant current

$${\dot{I}}_{P} ,$$

the secondary resonant current

$${\dot{I}}_{S}$$

and the secondary resonant voltage \dot{U}_{S} are different.

After the modulated first harmonic component and the modulated second harmonic component in each of the primary resonant current

$${\dot{I}}_{P} ,$$

the secondary resonant current

$${\dot{I}}_{S}$$

and the secondary resonant voltage \dot{U}_{S} are demodulated by the second filtering circuit 53 respectively, the two DC components of the first harmonic component in each of the primary resonant current

$${\dot{I}}_{P} ,$$

the secondary resonant current

$${\dot{I}}_{S}$$

and the secondary resonant voltage \dot{U}_{S} and the two DC components of the second harmonic component in each of the primary resonant current

$${\dot{I}}_{P} ,$$

the secondary resonant current

$${\dot{I}}_{S}$$

and the secondary resonant voltage \dot{U}_{S} are obtained. The micro control unit 54 calculates the amplitude and the phase of the first harmonic component in each of the primary resonant current

$${\dot{I}}_{P} ,$$

the secondary resonant current

$${\dot{I}}_{S}$$

and the secondary resonant voltage \dot{U}_{S} according to the two DC components of the first harmonic component in each of the primary resonant current

$${\dot{I}}_{P} ,$$

the secondary resonant current

$${\dot{I}}_{S}$$

and the secondary resonant voltage \dot{U}_{S}. The micro control unit 54 calculates the amplitude and the phase of the second harmonic component in each of the primary resonant current

$${\dot{I}}_{P} ,$$

the secondary resonant current

$${\dot{I}}_{S}$$

and the secondary resonant voltage \dot{U}_{S} according to the two DC components of the second harmonic component in each of the primary resonant current

$${\dot{I}}_{P} ,$$

the secondary resonant current

$${\dot{I}}_{S}$$

and the secondary resonant voltage \dot{U}_{S}.

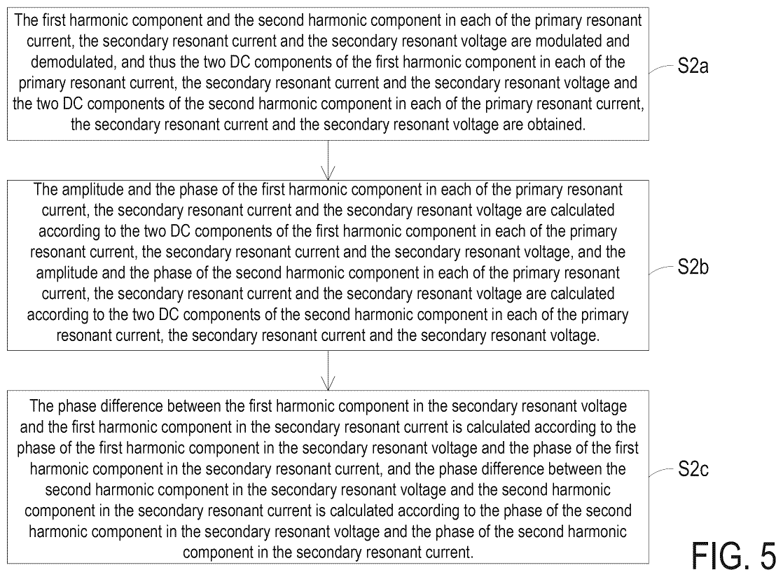

FIG. 5 is a flowchart illustrating the detailed procedures of the step S2 in FIG. 1 by using a first method. The step S2 includes the following steps.

In a step S2a, the first harmonic component and the second harmonic component in each of the primary resonant current

$${\dot{I}}_{P} ,$$

the secondary resonant current

$${\dot{I}}_{S}$$

and the secondary resonant voltage \dot{U}_{S} are modulated by the analog switch 52 respectively, and the modulated first harmonic component and the modulated second harmonic component in each of the primary resonant current

$${\dot{I}}_{P} ,$$

the secondary resonant current

$${\dot{I}}_{S}$$

and the secondary resonant voltage \dot{U}_{S} are demodulated by the second filtering circuit 53 respectively. Consequently, the two DC components of the first harmonic component and the two DC components of the second harmonic component in each of the primary resonant current

$${\dot{I}}_{P} ,$$

the secondary resonant current

$${\dot{I}}_{S}$$

and the secondary resonant voltage \dot{U}_{S} are obtained. That is, the two DC components of the first harmonic component in the primary resonant current

$${\dot{I}}_{P} ,$$

the two DC components of the second harmonic component in the primary resonant current

$${\dot{I}}_{P} ,$$

the two DC components of the first harmonic component in the secondary resonant current

$${\dot{I}}_{S} ,$$

the two DC components of the second harmonic component in the secondary resonant current

$${\dot{I}}_{S} ,$$

the two DC components of the first harmonic component in the secondary resonant voltage \dot{U}_{S} and the two DC components of the second harmonic component in the secondary resonant voltage \dot{U}s are obtained.

In a step S2b, the micro control unit 54 calculates the amplitude and the phase of the first harmonic component in the primary resonant current

$${\dot{I}}_{P}$$

according to the two DC components of the first harmonic component in the primary resonant current

$${\dot{I}}_{P} ,$$

and the micro control unit 54 calculates the amplitude and the phase of the second harmonic component in the primary resonant current

$${\dot{I}}_{P}$$

according to the two DC components of the second harmonic component in the primary resonant current

$${\dot{I}}_{P} .$$

Similarly, the micro control unit 54 calculates the amplitude and the phase of the first harmonic component in the secondary resonant current

$${\dot{I}}_{S}$$

according to the two DC components of the first harmonic component in the secondary resonant current

$${\dot{I}}_{S} ,$$

and the micro control unit 54 calculates the amplitude and the phase of the second harmonic component in the secondary resonant current

$${\dot{I}}_{S}$$

according to the two DC components of the second harmonic component in the secondary resonant current

$${\dot{I}}_{S} .$$

Similarly, the micro control unit 54 calculates the amplitude and the phase of the first harmonic component in the secondary resonant voltage \dot{U}_{S} according to the two DC components of the first harmonic component in the secondary resonant voltage \dot{U}_{S}, and the micro control unit 54 calculates the amplitude and the phase of the second harmonic component in the secondary resonant voltage \dot{U}_{S} according to the two DC components of the second harmonic component in the secondary resonant voltage \dot{U}s.

In a step S2c, the micro control unit 54 calculates the phase difference between the first harmonic component in the secondary resonant voltage \dot{U}_{S} and the first harmonic component in the secondary resonant current

$${\dot{I}}_{S}$$

according to the phase of the first harmonic component in the secondary resonant voltage \dot{U}_{S} and the phase of the first harmonic component in the secondary resonant current

$${\dot{I}}_{S} .$$

Similarly, the micro control unit 54 calculates the phase difference between the second harmonic component in the secondary resonant voltage \dot{U}_{S} and the second harmonic component in the secondary resonant current according to the phase of

$${\dot{I}}_{S}$$

according to the phase of the second harmonic component in the secondary resonant voltage \dot{U}_{S} and the phase of the second harmonic component in the secondary resonant current

$${\dot{I}}_{S} .$$

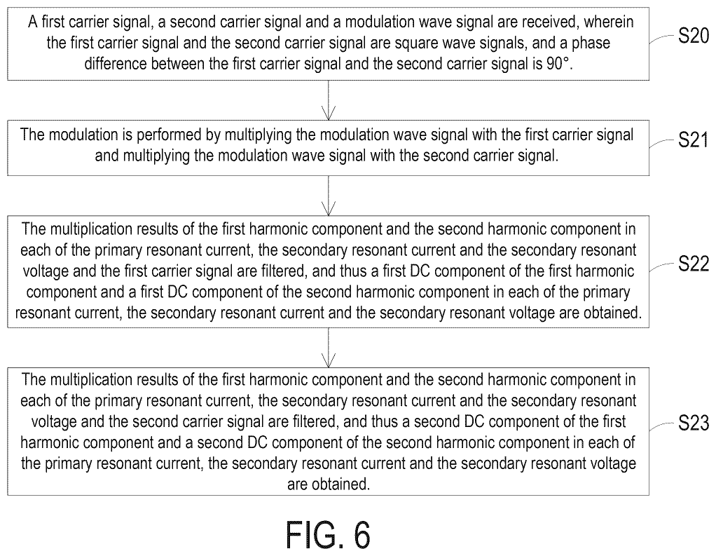

FIG. 6 is a flowchart illustrating sub-steps of the step S2 in the mutual inductance identification method of FIG. 1. In the step S2, the first harmonic component and the second harmonic component in each of the primary resonant current

$${\dot{I}}_{P} ,$$

the secondary resonant current

$${\dot{I}}_{S}$$

and the secondary resonant voltage \dot{U}_{S} are modulated respectively by performing the following sub-steps.

In a sub-step S20, the analog switch 52 receives a first carrier signal p₁(t), a second carrier signal p₂(t) and a modulation wave signal s(t), wherein the first carrier signal p₁(t) and the second carrier signal p₂(t) are square wave signals, and a phase difference between the first carrier signal p₁(t) and the second carrier signal p₂(t) is 90°.

In a sub-step S21, the analog switch 52 performs modulation by multiplying the modulation wave signal s(t) with the first carrier signal p₁(t) and multiplying the modulation wave signal s(t) with the second carrier signal p₂(t). Consequently, the following formulas are obtained:

$$s ( t ) * {p}_{1} ( t ) = A sin ( ω t + φ ) * {\sum }_{k = 1}^{∞} {B}_{k} sin ( k ωt ) \qquad ( 12 )$$

$$s ( t ) * {p}_{2} ( t ) = A sin ( ω t + φ ) * {\sum }_{k = I}^{∞} {B}_{k} cos ( k ω t ) \qquad ( 13 )$$

$$s ( t ) = A sin ( ω t + φ ) \qquad ( 14 )$$

$${p}_{1} ( t ) = {\sum }_{k = 1}^{∞} {B}_{k} sin ( k ω t ) \qquad ( 15 )$$

$${p}_{2} ( t ) = {\sum }_{k = 1}^{∞} {B}_{k} cos ( k ω t ) \qquad ( 16 )$$

In the above formulas, the modulation wave signal s(t) represents any one of the first harmonic component and the second harmonic component in each of the primary resonant current İ_{P}, the secondary resonant current İ_{S} and the secondary resonant voltage \dot{U}_{S}, A is the amplitude of the modulation wave signal s(t), ω is the angular frequency of the modulation wave signal s(t), φ is the phase of the modulation wave signal s(t), and Bk represents the amplitude of the first carrier signal p₁(t) and the amplitude of the second carrier signal p₂(t), wherein k is an odd number and represents the frequency of the first carrier signal p₁(t) and the frequency of the second carrier signal p₂(t). For example, if k is equal to 3, it means that the frequency is 3. In addition, the first carrier signal p₁(t) and the second carrier signal p₂(t) are obtained by performing Fourier transform on a square wave signal with the same frequency as the modulation wave signal s(t).

In the step S2, the modulated first harmonic component and the modulated second harmonic component in each of the primary resonant current İ_{P}, the secondary resonant current İ_{S} and the secondary resonant voltage \dot{U}_{S} are demodulated respectively by performing the following sub-steps.

After the sub-step S21, a sub-step S22 is performed. The multiplication results of the first carrier signal and the first harmonic component and the second harmonic component in each of the primary resonant current İ_{P}, the secondary resonant current İ_{S} and the secondary resonant voltage \dot{U}_{S} are filtered respectively by the second filtering circuit 53. Consequently, a first DC component of the first harmonic component and a first DC component of the second harmonic component in each of the primary resonant current İ_{P}, the secondary resonant current İ_{S} and the secondary resonant voltage \dot{U}_{S} are obtained. The first DC component is expressed as:

$$\frac{A {B}_{1} cos ( φ )}{2} ,$$

wherein B₁ is the value where k is equal to 1.

The first DC component is obtained by filtering the result of the formula (12). Consequently, the following formula (17) is obtained:

$$A sin ( ω t + φ ) * {Σ}_{k = 1}^{∞} {B}_{k} sin ( k ω t ) = \frac{A {B}_{1} cos ( φ )}{2} - \frac{A {B}_{1} cos ( φ ) cos ( 2 ω t )}{2} + \frac{{AB}_{1} sin ( φ ) sin ( 2 ω t )}{2} + A sin ( ω t + φ ) + {Σ}_{k = 3}^{∞} {B}_{k} sin ( k ω t ) \qquad ( 17 )$$

In the sub-step S23. The multiplication results of the second carrier signal and the first harmonic component and the second harmonic component in each of the primary resonant current İ_{P}, the secondary resonant current İ_{S} and the secondary resonant voltage \dot{U}_{S} are filtered by the second filtering circuit 53 respectively. Consequently, a second DC component of the first harmonic component and a second DC component of the second harmonic component in each of the primary resonant current İ_{P}, the secondary resonant current İ_{S} and the secondary resonant voltage \dot{U}_{S} are obtained. The second DC component is expressed as:

$$\frac{A {B}_{1} sin ( φ )}{2} .$$

The second DC component is obtained by filtering the result of the formula (13). Consequently, the following formula (18) is obtained:

$$A sin ( ω t + φ ) * {Σ}_{k = 1}^{∞} {B}_{k} cos ( k ω t ) = \frac{A {B}_{1} sin ( φ )}{2} + \frac{A {B}_{1} sin ( φ ) cos ( 2 ω t )}{2} + \frac{A {B}_{1} cos ( φ ) sin ( 2 ω t )}{2} + A sin ( ω t + φ ) * {\sum }_{k = 3}^{∞} {B}_{k} cos ( k ω t ) \qquad ( 18 )$$

In the step S2, the micro control unit 54 calculates the amplitude and the phase of the first harmonic component in each of the primary resonant current İ_{P}, the secondary resonant current İ_{S} and the secondary resonant voltage \dot{U}_{S} and calculates the amplitude and the phase of the second harmonic component in each of the primary resonant current İ_{P}, the secondary resonant current İ_{S} and the secondary resonant voltage \dot{U}_{S} according to the following formulas:

$$\{ \begin{matrix}{C}_{1} = \frac{{AB}_{1} cos ( φ )}{2} & ( 19 ) \\ {C}_{2} = \frac{{AB}_{1} sin ( φ )}{2} & ( 20 )\end{matrix}$$

$$φ = arctan \frac{{C}_{1}}{{C}_{2}} \qquad ( 21 )$$

$$A = \frac{2 {C}_{1}}{{B}_{1} cos ( φ )} \qquad ( 22 )$$

In the above formulas, C₁ is the first DC component of any one of the first harmonic component and the second harmonic component in each of the primary resonant current İ_{P}, the secondary resonant current İ_{S} and the secondary resonant voltage \dot{U}_{S}, C₂ corresponds to C₁ and is the second DC component of any one of the first harmonic component and the second harmonic component in each of the primary resonant current İ_{P}, the secondary resonant current İ_{S} and the secondary resonant voltage \dot{U}_{S}, φ corresponds to C₁ and C₂ and is the phase of any one of the first harmonic component and the second harmonic component in each of the primary resonant current İ_{P}, the secondary resonant current İ_{S} and the secondary resonant voltage \dot{U}_{S}, and A corresponds to C₁ and C₂ and is the amplitude of any one of the first harmonic component and the second harmonic component in each of the primary resonant current İ_{P}, the secondary resonant current İ_{S} and the secondary resonant voltage \dot{U}_{S}.

It is noted that the formulas to calculate the phase and the amplitude are not restricted to the formulas (21) and (22).

In the step S2, the amplitudes of the two DC components of the first harmonic component in each of the primary resonant current İ_{P}, the secondary resonant current İ_{S} and the secondary resonant voltage \dot{U}_{S} and the amplitudes of the two DC components of the second harmonic component in each of the primary resonant current İ_{P}, the secondary resonant current İ_{S} and the secondary resonant voltage \dot{U}_{S} are adjusted by the differential amplifier 55 of the mutual inductance calculation device 5, and then subjected to analog/digital conversion by the ADC conversion circuit 56 of the mutual inductance calculation device 5. Consequently, the micro control unit 54 calculates the amplitude and the phase of the first harmonic component in each of the primary resonant current İ_{P}, the secondary resonant current İ_{S} and the secondary resonant voltage \dot{U}_{S} and calculates the amplitude and the phase of the second harmonic component in each of the primary resonant current İ_{P}, the secondary resonant current İ_{S} and the secondary resonant voltage \dot{U}_{S}.

In the step S3, the micro control unit 54 calculates the mutual inductance parameter between the primary circuit 2 and the secondary circuit 4 according to the amplitude of the first harmonic component in each of the primary resonant current İ_{P}, the secondary resonant current İ_{S} and the secondary resonant voltage \dot{U}_{S}, the amplitude of the second harmonic component in each of the primary resonant current İ_{P}, the secondary resonant current İ_{S} and the secondary resonant voltage \dot{U}_{S}, the phase difference between the first harmonic component in the secondary resonant voltage \dot{U}_{S} and the first harmonic component in the secondary resonant current İ_{S} and the phase difference between the second harmonic component in the secondary resonant voltage \dot{U}_{S} and the second harmonic component in the secondary resonant current İ_{S}. For example, the above paraments are introduced into the formula (10) and the formula (11) to calculate the mutual inductance parameters between the primary circuit 2 and the secondary circuit 4. For the formula (10) and the formula (11), i is equal to 1 and 2. If i is 1, the i-th harmonic component is the first harmonic component. If i is 2, the i-th harmonic component is the second harmonic component.

In non-ideal situations, there is a certain frequency difference Δf between the square wave signal received by the analog switch 52 (e.g., the first carrier signal p₁(t) and the second carrier signal p₂(t)) and the driving signal of the primary circuit 2. For example, Δf≤100 Hz. As shown in the following formula, after the output signal from the analog switch 52 is filtered by the second filtering circuit 53, a low-frequency AC component

$$\frac{A {B}_{1} sin ( Δ ω t + φ )}{2} ,$$

rather than an ideal DC component, is obtained.

$$A sin ( ω t + φ ) * {\sum }_{k = 1}^{∞} {B}_{k} sin [ k ( ω + Δω ) t ] = \frac{A {B}_{1} sin ( Δ ω t + φ )}{2} - \frac{A {B}_{1} cos [ ( 2 ω + Δ ω ) t + φ ]}{2} + A sin ( ω t + φ ) * {\sum }_{k = 3}^{∞} {B}_{k} sin [ k ( ω + Δ ω ) t ] \qquad ( 23 )$$

Since the output signal from the analog switch 52 and filtered by the second filtering circuit 53 is the low-frequency AC component, the present disclosure further provides a second method of calculating the amplitude of the first harmonic component in each of the primary resonant current İ_{P}, the secondary resonant current İ_{S} and the secondary resonant voltage \dot{U}_{S}, the amplitude of the second harmonic component in each of the primary resonant current İ_{P}, the secondary resonant current İ_{S} and the secondary resonant voltage \dot{U}_{S}, the phase difference between the first harmonic component in the secondary resonant voltage \dot{U}_{S} and the first harmonic component in the secondary resonant current İ_{S} and the phase difference between the second harmonic component in the secondary resonant voltage \dot{U}_{S} and the second harmonic component in the secondary resonant current İ_{S}. In the mutual inductance identification method and the mutual inductance calculation device, similar elements are represented with similar element numbers and are not redundantly described hereinafter.

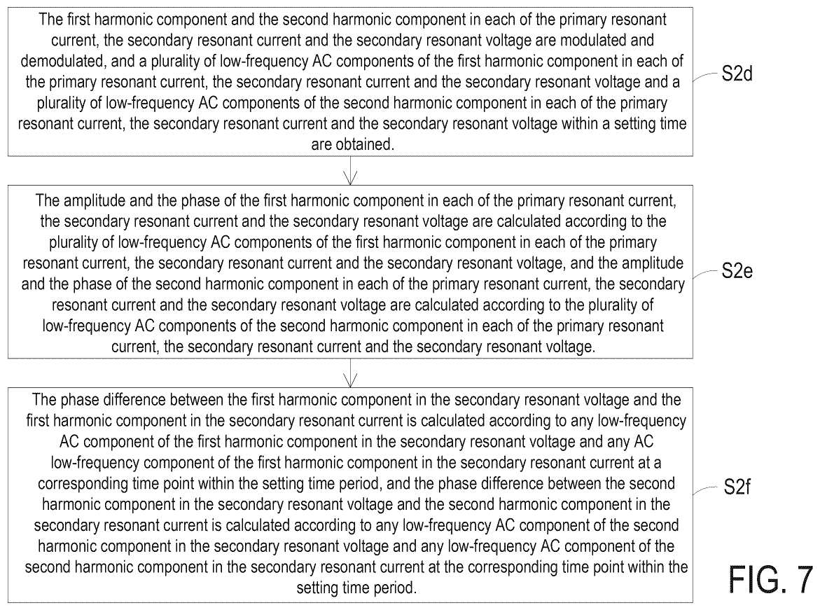

FIG. 7 is a flowchart illustrating the detailed procedures of the step S2 in FIG. 1 by using a second method. The step S2 includes the following steps.

In a step S2d, the modulated first harmonic component and the modulated second harmonic component in each of the primary resonant current İ_{P}, the secondary resonant current İ_{S} and the secondary resonant voltage \dot{U}_{S} are demodulated by the second filtering circuit 53 respectively. Consequently, a plurality of low-frequency AC components of the first harmonic component in each of the primary resonant current İ_{P}, the secondary resonant current İ_{S} and the secondary resonant voltage \dot{U}_{S} and a plurality of low-frequency AC components of the second harmonic component in each of the primary resonant current İ_{P}, the secondary resonant current İ_{S} and the secondary resonant voltage \dot{U}_{S} within a setting time period are obtained.

In a step S2e, the micro control unit 54 calculates the amplitude of the first harmonic component in each of the primary resonant current İ_{P}, the secondary resonant current İ_{S} and the secondary resonant voltage \dot{U}_{S} according to the plurality of low-frequency AC components of the first harmonic component in each of the primary resonant current İ_{P}, the secondary resonant current İ_{S} and the secondary resonant voltage \dot{U}_{S}, and the micro control unit 54 calculates the amplitude of the second harmonic component in each of the primary resonant current İ_{P}, the secondary resonant current İ_{S} and the secondary resonant voltage \dot{U}_{S} according to the plurality of low-frequency AC components of the second harmonic component in each of the primary resonant current İ_{P}, the secondary resonant current İ_{S} and the secondary resonant voltage \dot{U}_{S}.

In a step S2f, the micro control unit 54 calculates the phase difference between the first harmonic component in the secondary resonant voltage \dot{U}_{S} and the first harmonic component in the secondary resonant current İ_{S} according to any low-frequency AC component of the first harmonic component in the secondary resonant voltage \dot{U}_{S} and any low-frequency AC component of the first harmonic component in the secondary resonant current İ_{S} at the corresponding time point within the setting time period, and the micro control unit 54 calculates the phase difference between the second harmonic component in the secondary resonant voltage \dot{U}_{S} and the second harmonic component in the secondary resonant current İ_{S} according to any low-frequency AC component of the second harmonic component in the secondary resonant voltage \dot{U}_{S} and any low-frequency AC component of the second harmonic component in the secondary resonant current İ_{S} at the corresponding time point within the setting time period.

The amplitude of the first harmonic component in each of the primary resonant current İ_{P}, the secondary resonant current İ_{S} and the secondary resonant voltage \dot{U}_{S} and the amplitude of the second harmonic component in each of the primary resonant current İ_{P}, the secondary resonant current İ_{S} and the secondary resonant voltage \dot{U}_{S} may be obtained according to the maximum value of the low-frequency AC component

$$\frac{A {B}_{1} sin ( Δ ω t + φ )}{2}$$

within the setting time period. The setting time period is a complete low-frequency AC cycle. For example, the setting time period is 20 milliseconds, but is not limited thereto.

The following formula (24) can be used to obtain the amplitude of the first harmonic component in the secondary resonant voltage \dot{U}_{S}. It is noted that the formula (24) can be applied to obtain other parameters, e.g., the amplitude of the first harmonic component or the second harmonic component in each of the secondary resonant current

$${\dot{I}}_{S}$$

and the secondary resonant voltage \dot{U}s.

$$\vert {U}_{S 1}^{.} \vert = max [ \frac{A {B}_{1} sin ( Δ ω t + φ )}{2} ] * \frac{2}{{B}_{1}} \qquad ( 24 )$$

The phase difference between the first harmonic component in the secondary resonant voltage \dot{U}_{S} and the first harmonic component in the secondary resonant current

$${\dot{I}}_{S}$$

and the phrase difference between the second harmonic component in the secondary resonant voltage \dot{U}_{S} and the second harmonic component in the secondary resonant current

$${\dot{I}}_{S}$$

can be obtained according to the similar method. For example, after any low-frequency AC component of the first harmonic component in the secondary resonant voltage \dot{U}_{S} and any low-frequency AC component of the first harmonic component in the secondary resonant current

$${\dot{I}}_{S}$$

at the corresponding time point are processed with an inverse trigonometric function, the transient phase of the first harmonic component in the secondary resonant voltage \dot{U}_{S} and the transient phase of the first harmonic component in the secondary resonant current

$${\dot{I}}_{S}$$

are calculated according to the following formulas (25) and (26). The phase difference between the first harmonic component in the secondary resonant voltage \dot{U}_{S} and the first harmonic component in the secondary resonant current

$${\dot{I}}_{S}$$

can be calculated according to the two transient phases and the following formula (27).

$${U}_{S 1}^{.} = \frac{{A}_{1} {B}_{1} sin ( Δ ω t + {φ}_{1} )}{2} \qquad ( 25 )$$

$${I}_{S 1}^{.} = \frac{{A}_{2} {B}_{1} sin ( Δ ω t + {φ}_{2} )}{2} \qquad ( 26 )$$

$${θ}_{1} = {φ}_{1} - {φ}_{2} \qquad ( 27 )$$

By using the second method, the micro control unit 54 calculates the mutual inductance parameter between the primary circuit 2 and the secondary circuit 4 according to the amplitude of the first harmonic component in each of the primary resonant current İ_{P}, the secondary resonant current

$${\dot{I}}_{S}$$

and the secondary resonant voltage \dot{U}_{S}, the amplitude of the second harmonic component in each of the primary resonant current İ_{P}, the secondary resonant current

$${\dot{I}}_{S}$$

and the secondary resonant voltage \dot{U}_{S}, the phase difference between the first harmonic component in the secondary resonant voltage \dot{U}_{S} and the first harmonic component in the secondary resonant current

$${\dot{I}}_{S}$$

and the phase difference between the second harmonic component in the secondary resonant voltage \dot{U}_{S} and the second harmonic component in the secondary resonant current

$${\dot{I}}_{S} .$$

For example, the above paraments are introduced into the formula (10) and the formula (11) to calculate the mutual inductance parameters between the primary circuit 2 and the secondary circuit 4. For the formula (10) and the formula (11), i is equal to 1 and 2. If i is 1, the i-th harmonic component is the first harmonic component. If i is 2, the i-th harmonic component is the second harmonic component.

The mutual inductance identification method and the mutual inductance calculation device can be used to achieve the following technical effects listed in Table 1. If the distance between the primary coil L_{P} and the secondary coil L_{S} is large (≥20 mm) or small (≤4 mm), the measurement error of the mutual inductance parameter calculated by using the method of the present disclosure is about 3%. If the distance between the primary coil L_{P} and the secondary coil L_{S} is equal to about 10 mm, the measurement error of the mutual inductance parameter calculated by using the method of the present disclosure is about 1%. If the distance between the primary coil L_{P} and the secondary coil L_{S} is greater than 10 mm, the measurement error of the mutual inductance parameter calculated by using the method of the present disclosure is slightly smaller than the actual value. If the distance between the primary coil L_{P} and the secondary coil L_{S} is greater than 6 mm, the measurement error of the mutual inductance parameter calculated by using the method of the present disclosure is slightly larger than the actual value. Since the overall measurement error of the mutual inductance parameter calculated by using the method of the present disclosure does not exceed 3%, good measurement accuracy can be achieved.

TABLE 1

| | Minimum | Maximum | Actual | Error of | Error of |
|---|---|---|---|---|---|
| | calculated | calculated | value | minimum | maximum |
| | value of | value of | of | calculated | calculated |
| | mutual | mutual | mutual | value of | value of |
| | inductance | inductance | inductance | mutual | mutual |
| Distance/ | parameter/ | parameter/ | parameter/ | inductance | inductance |
| mm | uH | uH | uH | parameter | parameter |
| 2 | 139.6 | 140.3 | 136.3 | 2.42% | 2.93% |
| 4 | 125.7 | 126.7 | 123.1 | 2.11% | 2.92% |
| 6 | 113.7 | 114.3 | 113.3 | 0.35% | 0.88% |
| 10 | 95.4 | 95.6 | 96.7 | −1.34% | −1.14% |
| 20 | 66.6 | 66.7 | 67.7 | −1.62% | −1.48% |
| 30 | 48.7 | 48.8 | 50.2 | −2.99% | −2.79% |

From the above descriptions, the present disclosure provides a mutual inductance identification method and a mutual inductance calculation device using the method. The mutual inductance identification method and the mutual inductance calculation device are not related to the circuit resonance state and the load size. Consequently, the adverse effects of other factors (e.g., the resonance point offset or the load change) can be mostly avoided to ensure that the mutual inductance measurement has good accuracy.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A mutual inductance identification method for a wireless power transmission system, the wireless power transmission system comprising a primary circuit, a resonant cavity and a secondary circuit, the mutual inductance identification method comprising steps of:
(S1) sampling a primary resonant current of the primary circuit, sampling a secondary resonant current and a secondary resonant voltage of the secondary circuit, and filtering the primary resonant current, the secondary resonant current and the secondary resonant voltage respectively so as to obtain a first harmonic component and a second harmonic component in each of the primary resonant current, the secondary resonant current and the secondary resonant voltage, wherein a frequency of the first harmonic component and a frequency of the second harmonic component in each of the primary resonant current, the secondary resonant current and the secondary resonant voltage are different;
(S2) modulating and demodulating the first harmonic component and the second harmonic component in each of the primary resonant current, the secondary resonant current and the secondary resonant voltage respectively, so that an amplitude of the first harmonic component in each of the primary resonant current, the secondary resonant current and the secondary resonant voltage, an amplitude of the second harmonic component in each of the primary resonant current, the secondary resonant current and the secondary resonant voltage, a phase difference between the first harmonic component in the secondary resonant voltage and the first harmonic component in the secondary resonant current and a phase difference between the second harmonic component in the secondary resonant voltage and the second harmonic component in the secondary resonant current are obtained; and
(S3) calculating a mutual inductance parameter between the primary circuit and the secondary circuit according to the amplitude of the first harmonic component in each of the primary resonant current, the secondary resonant current and the secondary resonant voltage, the amplitude of the second harmonic component in each of the primary resonant current, the secondary resonant current and the secondary resonant voltage, the phase difference between the first harmonic component in the secondary resonant voltage and the first harmonic component in the secondary resonant current and the phase difference between the second harmonic component in the secondary resonant voltage and the second harmonic component in the secondary resonant current.

2. The mutual inductance identification method according to claim 1, wherein the step (S2) comprises steps of:
modulating and demodulating the first harmonic component and the second harmonic component in each of the primary resonant current, the secondary resonant current and the secondary resonant voltage respectively, so that two DC components of the first harmonic component in each of the primary resonant current, the secondary resonant current and the secondary resonant voltage and two DC components of the second harmonic component in each of the primary resonant current, the secondary resonant current and the secondary resonant voltage are obtained;
calculating the amplitude and a phase of the first harmonic component in each of the primary resonant current, the secondary resonant current and the secondary resonant voltage according to the two DC components of the first harmonic component in each of the primary resonant current, the secondary resonant current and the secondary resonant voltage, and calculating the amplitude and a phase of the second harmonic component in each of the primary resonant current, the secondary resonant current and the secondary resonant voltage according to the two DC components of the second harmonic component in each of the primary resonant current, the secondary resonant current and the secondary resonant voltage; and
calculating the phase difference between the first harmonic component in the secondary resonant voltage and the first harmonic component in the secondary resonant current according to the phase of the first harmonic component in the secondary resonant voltage and the phase of the first harmonic component in the secondary resonant current, and calculating the phase difference between the second harmonic component in the secondary resonant voltage and the second harmonic component in the secondary resonant current according to the phase of the second harmonic component in the secondary resonant voltage and the phase of the second harmonic component in the secondary resonant current.

3. The mutual inductance identification method according to claim 1, wherein the step (S2) comprises steps of:
modulating and demodulating the first harmonic component and the second harmonic component in each of the primary resonant current, the secondary resonant current and the secondary resonant voltage respectively, so that a plurality of low-frequency AC components of the first harmonic component in each of the primary resonant current, the secondary resonant current and the secondary resonant voltage and a plurality of low-frequency AC components of the second harmonic component in each of the primary resonant current, the secondary resonant current and the secondary resonant voltage within a setting time period are obtained;
calculating the amplitude of the first harmonic component in each of the primary resonant current, the secondary resonant current and the secondary resonant voltage according to the plurality of low-frequency AC components of the first harmonic component in each of the primary resonant current, the secondary resonant current and the secondary resonant voltage, and calculating the amplitude of the second harmonic component in each of the primary resonant current, the secondary resonant current and the secondary resonant voltage according to the plurality of low-frequency AC components of the second harmonic component in each of the primary resonant current, the secondary resonant current and the secondary resonant voltage; and
calculating the phase difference between the first harmonic component in the secondary resonant voltage and the first harmonic component in the secondary resonant current according to any low-frequency AC component of the first harmonic component in the secondary resonant voltage and any low-frequency AC component of the first harmonic component in the secondary resonant current at a corresponding time point within the setting time period, and calculating the phase difference between the second harmonic component in the secondary resonant voltage and the second harmonic component in the secondary resonant current according to any low-frequency AC component of the second harmonic component in the secondary resonant voltage and any low-frequency AC component of the second harmonic component in the secondary resonant current at the corresponding time point within the setting time period.

4. The mutual inductance identification method according to claim 3, wherein a maximum value of the plurality of low-frequency AC components of the first harmonic component in each of the primary resonant current, the secondary resonant current and the secondary resonant voltage within the setting time period corresponds to the amplitude of the first harmonic component in each of the primary resonant current, the secondary resonant current and the secondary resonant voltage respectively, and a maximum value of the plurality of low-frequency AC components of the second harmonic component in each of the primary resonant current, the secondary resonant current and the secondary resonant voltage within the setting time period corresponds to the amplitude of the second harmonic component in each of the primary resonant current, the secondary resonant current and the secondary resonant voltage respectively.

5. The mutual inductance identification method according to claim 3, wherein after any low-frequency AC component of the first harmonic component in the secondary resonant voltage and any low-frequency AC component of the first harmonic component in the secondary resonant current at the corresponding time point within the setting time period are processed with an inverse trigonometric function, the phase difference between the first harmonic component in the secondary resonant voltage and the first harmonic component in the secondary resonant current is obtained, wherein after any low-frequency AC component of the second harmonic component in the secondary resonant voltage and any low-frequency AC component of the second harmonic component in the secondary resonant current at the corresponding time point within the setting time period are processed with an inverse trigonometric function, the phase difference between the second harmonic component in the secondary resonant voltage and the second harmonic component in the secondary resonant current is obtained.

6. The mutual inductance identification method according to claim 1, wherein the frequency of the first harmonic component in the primary resonant current, the frequency of the first harmonic component in the secondary resonant current and the frequency of the first harmonic component in the secondary resonant voltage are identical, and the frequency of the second harmonic component in the primary resonant current, the frequency of the second harmonic component in the secondary resonant current and the frequency of the second harmonic component in the secondary resonant voltage are identical, wherein the first harmonic component and the second harmonic component are harmonic components below a fifth-order frequency.

7. The mutual inductance identification method according to claim 6, wherein the first harmonic component is a fundamental component, and the second harmonic component is a third harmonic component.

8. The mutual inductance identification method according to claim 2, wherein in the step (S2), the first harmonic component and the second harmonic component in the primary resonant current, the first harmonic component and the second harmonic component in the secondary resonant current and the first harmonic component and the second harmonic component in the secondary resonant voltage are modulated respectively by performing sub-steps of:
(S20) receiving a first carrier signal p₁(t), a second carrier signal p₂(t) and a modulation wave signal s(t), wherein the first carrier signal p₁(t) and the second carrier signal p₂(t) are square wave signals, and a phase difference between the first carrier signal p₁(t) and the second carrier signal p₂(t) is 90°; and
(S21) multiplying the modulation wave signal s(t) with the first carrier signal p₁(t) and multiplying the modulation wave signal s(t) with the second carrier signal p₂(t), so that following formulas are obtained:
$$s ( t ) * {p}_{1} ( t ) = A sin ( ω t + φ ) * {\sum }_{k = 1}^{∞} {B}_{k} sin ( k ω t ) \qquad ( 1 )$$
$$( t ) * {p}_{2} ( t ) = A sin ( ω t + φ ) * {\sum }_{k = 1}^{∞} {B}_{k} cos ( k ω t ) \qquad ( 2 )$$
$$s ( t ) = A sin ( ω t + φ ) \qquad ( 3 )$$
$${p}_{1} ( t ) = {\sum }_{k = 1}^{∞} {B}_{k} sin ( k ω t ) \qquad ( 4 )$$
$${p}_{2} ( t ) = {\sum }_{k = 1}^{∞} {B}_{k} cos ( k ω t ) \qquad ( 5 )$$
wherein the modulation wave signal s(t) represents any one of the first harmonic component and the second harmonic component in each of the primary resonant current, the secondary resonant current and the secondary resonant voltage, A is an amplitude of the modulation wave signal s(t), ω is an angular frequency of the modulation wave signal s(t), φ is a phase of the modulation wave signal s(t), and Bk represents an amplitude of the first carrier signal p₁(t) and an amplitude of the second carrier signal p₂(t), wherein k is an odd number and represents a frequency of the first carrier signal p₁(t) and a frequency of the second carrier signal p₂(t).

9. The mutual inductance identification method according to claim 8, wherein in the step (S2), the modulated first harmonic component and the modulated second harmonic component in the primary resonant current, the modulated first harmonic component and the modulated second harmonic component in the secondary resonant current and the modulated first harmonic component and the modulated second harmonic component in the secondary resonant voltage are demodulated respectively by performing sub-steps of:
(S22) filtering multiplication results of the first carrier signal and the first harmonic component and the second harmonic component in each of the primary resonant current, the secondary resonant current and the secondary resonant voltage respectively, so that a first DC component of the first harmonic component and a first DC component of the second harmonic component in each of the primary resonant current, the secondary resonant current and the secondary resonant voltage are obtained, wherein the first DC component is expressed as:
$$\frac{A {B}_{1} cos ( φ )}{2}$$
wherein B₁ is a value where k is equal to 1; and
(S23) filtering multiplication results of the second carrier signal and the first harmonic component and the second harmonic component in each of the primary resonant current, the secondary resonant current and the secondary resonant voltage respectively, so that a second DC component of the first harmonic component and a second DC component of the second harmonic component in each of the primary resonant current, the secondary resonant current and the secondary resonant voltage are obtained, wherein second DC component is expressed as:
$$\frac{A {B}_{1} sin ( φ )}{2} .$$

10. The mutual inductance identification method according to claim 9, wherein the amplitude and the phase of the first harmonic component in each of the primary resonant current, the secondary resonant current and the secondary resonant voltage, and the amplitude and the phase of the second harmonic component in each of the primary resonant current, the secondary resonant current and the secondary resonant voltage are calculated according to following formulas:
$$\{ \begin{matrix}{C}_{1} = \frac{A {B}_{1} cos ( φ )}{2} \\ {C}_{2} = \frac{A {B}_{1} sin ( φ )}{2}\end{matrix} \qquad ( 6 )$$
$$φ = arctan \frac{{C}_{1}}{{C}_{2}} \qquad ( 7 )$$
$$A = \frac{2 {C}_{1}}{{B}_{1} cos ( φ )} \qquad ( 8 )$$
wherein C₁ is the first DC component of any one of the first harmonic component and the second harmonic component in each of the primary resonant current, the secondary resonant current and the secondary resonant voltage, C₂ corresponds to C₁ and is the second DC component of any one of the first harmonic component and the second harmonic component in each of the primary resonant current, the secondary resonant current and the secondary resonant voltage, φ corresponds to C₁ and C₂ and is the phase of any one of the first harmonic component and the second harmonic component in each of the primary resonant current, the secondary resonant current and the secondary resonant voltage, and A corresponds to C₁ and C₂ and is the amplitude of any one of the first harmonic component and the second harmonic component in each of the primary resonant current, the secondary resonant current and the secondary resonant voltage.

11. The mutual inductance identification method according to claim 2, wherein the step (S2) further comprises steps of: adjusting amplitudes of the two DC components of the first harmonic component in each of the primary resonant current, the secondary resonant current and the secondary resonant voltage and amplitudes of the two DC components of the second harmonic component in each of the primary resonant current, the secondary resonant current and the secondary resonant voltage, performing an analog/digital conversion on the adjusted amplitudes, and calculating the amplitude and the phase of the first harmonic component in each of the primary resonant current, the secondary resonant current and the secondary resonant voltage and the amplitude and the phase of the second harmonic component in each of the primary resonant current, the secondary resonant current and the secondary resonant voltage.

12. The mutual inductance identification method according to claim 1, wherein in the step (S3), the mutual inductance parameter is calculated according to following formulas:
$${ω}_{i} M \vert {I}_{P ι}^{.} \vert = \sqrt{{( ( {ω}_{i} {L}_{S} - \frac{1}{{ω}_{i} {C}_{S}} ) \vert {I}_{S ι}^{.} \vert - \vert {U}_{S ι}^{.} \vert sin {θ}_{i} )}^{2} + {( \vert {U}_{S ι}^{.} \vert cos {θ}_{i} )}^{2}} \qquad ( 9 )$$
$${θ}_{i} = {φ}_{{U}_{S i}} - {φ}_{{J}_{S i}} \qquad ( 10 )$$
wherein \dot{U}_{Sι} is an i-th harmonic component in the secondary resonant voltage, L_{S} is a self-inductance of a secondary winding of the secondary circuit, C_{S} is a capacitance of a secondary compensation capacitor of the secondary circuit, İ_{Sι} is an i-th harmonic component in the secondary resonant current, M is the mutual inductance parameter, ωᵢ is the angular frequency at the i-th harmonic component,
$${\dot{I}}_{P ι}$$
is an i-th harmonic component in the primary resonant current, θᵢ is a phase difference between the i-th harmonic component in the secondary resonant voltage and the i-th harmonic component in the secondary resonant current, φ_{U}_{_{Si}} is a phase of the i-th harmonic component in the secondary resonant voltage, and φ_{I}_{_{Si}} is a phase of the i-th harmonic component in the secondary resonant current, wherein if i=1, the i-th harmonic component is the first harmonic component, wherein if i=2, the i-th harmonic component is the second harmonic component.

13. A mutual inductance calculation device for a wireless power transmission system, the wireless power transmission system comprising a primary circuit, a resonant cavity and a secondary circuit, the mutual inductance calculation device comprising:
a sampling circuit for sampling a primary resonant current of the primary circuit and sampling a secondary resonant current and a secondary resonant voltage of the secondary circuit;
a first filtering circuit configured to filter the primary resonant current, the secondary resonant current and the secondary resonant voltage respectively to obtain a first harmonic component and a second harmonic component in each of the primary resonant current, the secondary resonant current and the secondary resonant voltage, wherein a frequency of the first harmonic component and a frequency of the second harmonic component in each of the primary resonant current, the secondary resonant current and the secondary resonant voltage are different;
an analog switch configured to modulate the first harmonic component and the second harmonic component in each of the primary resonant current, the secondary resonant current and the secondary resonant voltage respectively;
a second filtering circuit configured to demodulate the modulated first harmonic component and the modulated second harmonic component in each of the primary resonant current, the secondary resonant current and the secondary resonant voltage respectively; and
a micro control unit configured to obtain an amplitude of the first harmonic component in each of the primary resonant current, the secondary resonant current and the secondary resonant voltage and a phase difference between the first harmonic component in the secondary resonant voltage and the first harmonic component in the secondary resonant current according to the demodulated first harmonic component in each of the primary resonant current, the secondary resonant current and the secondary resonant voltage, obtain an amplitude of the second harmonic component in each of the primary resonant current, the secondary resonant current and the secondary resonant voltage and a phase difference between the second harmonic component in the secondary resonant voltage and the second harmonic component in the secondary resonant current according to the demodulated second harmonic component in each of the primary resonant current, the secondary resonant current and the secondary resonant voltage, calculate a mutual inductance parameter between the primary circuit and the secondary circuit according to the amplitude of the first harmonic component in each of the primary resonant current, the secondary resonant current and the secondary resonant voltage, the amplitude of the second harmonic component in each of the primary resonant current, the secondary resonant current and the secondary resonant voltage, the phase difference between the first harmonic component in the secondary resonant voltage and the first harmonic component in the secondary resonant current and the phase difference between the second harmonic component in the secondary resonant voltage and the second harmonic component in the secondary resonant current.

14. The mutual inductance calculation device according to claim 13, wherein after the modulated first harmonic component and the modulated second harmonic component in each of the primary resonant current, the secondary resonant current and the secondary resonant voltage are demodulated respectively by the second filtering circuit, the micro control unit obtains two DC components of the first harmonic component in each of the primary resonant current, the secondary resonant current and the secondary resonant voltage and two DC components of the second harmonic component in each of the primary resonant current, the secondary resonant current and the secondary resonant voltage, wherein the micro control unit calculates the amplitude and a phase of the first harmonic component in each of the primary resonant current, the secondary resonant current and the secondary resonant voltage according to the two DC components of the first harmonic component in each of the primary resonant current, the secondary resonant current and the secondary resonant voltage, and the micro control unit calculates the amplitude and a phase of the second harmonic component in each of the primary resonant current, the secondary resonant current and the secondary resonant voltage according to the two DC components of the second harmonic component in each of the primary resonant current, the secondary resonant current and the secondary resonant voltage, wherein the micro control unit calculates the phase difference between the first harmonic component in the secondary resonant voltage and the first harmonic component in the secondary resonant current according to the phase of the first harmonic component in the secondary resonant voltage and the phase of the first harmonic component in the secondary resonant current, and the micro control unit calculates the phase difference between the second harmonic component in the secondary resonant voltage and the second harmonic component in the secondary resonant current according to the phase of the second harmonic component in the secondary resonant voltage and the phase of the second harmonic component in the secondary resonant current.

15. The mutual inductance calculation device according to claim 13, wherein the second filtering circuit demodulates the modulated first harmonic component and the modulated second harmonic component in each of the primary resonant current, the secondary resonant current and the secondary resonant voltage respectively, so that a plurality of low-frequency AC components of the first harmonic component in each of the primary resonant current, the secondary resonant current and the secondary resonant voltage and a plurality of low-frequency AC components of the second harmonic component in each of the primary resonant current, the secondary resonant current and the secondary resonant voltage within a setting time period are obtained, wherein the micro control unit calculates the amplitude of the first harmonic component in each of the primary resonant current, the secondary resonant current and the secondary resonant voltage according to the plurality of low-frequency AC components of the first harmonic component in each of the primary resonant current, the secondary resonant current and the secondary resonant voltage, and the micro control unit calculates the amplitude of the second harmonic component in each of the primary resonant current, the secondary resonant current and the secondary resonant voltage according to the plurality of low-frequency AC components of the second harmonic component in each of the primary resonant current, the secondary resonant current and the secondary resonant voltage, wherein the micro control unit calculates the phase difference between the first harmonic component in the secondary resonant voltage and the first harmonic component in the secondary resonant current according to any low-frequency AC component of the first harmonic component in the secondary resonant voltage and any AC low-frequency component of the first harmonic component in the secondary resonant current at a corresponding time point within the setting time period, and the micro control unit calculates the phase difference between the second harmonic component in the secondary resonant voltage and the second harmonic component in the secondary resonant current according to any low-frequency AC component of the second harmonic component in the secondary resonant voltage and any low-frequency AC component of the second harmonic component in the secondary resonant current at the corresponding time point within the setting time period.

16. The mutual inductance calculation device according to claim 15, wherein a maximum value of the plurality of low-frequency AC components of the first harmonic component in each of the primary resonant current, the secondary resonant current and the secondary resonant voltage within the setting time period corresponds to the amplitude of the first harmonic component in each of the primary resonant current, the secondary resonant current and the secondary resonant voltage respectively, and a maximum value of the plurality of low-frequency AC components of the second harmonic component in each of the primary resonant current, the secondary resonant current and the secondary resonant voltage within the setting time period corresponds to the amplitude of the second harmonic component in each of the primary resonant current, the secondary resonant current and the secondary resonant voltage respectively.

17. The mutual inductance calculation device according to claim 15, wherein after any low-frequency AC component of the first harmonic component in the secondary resonant voltage and any low-frequency AC component of the first harmonic component in the secondary resonant current at the corresponding time point within the setting time period are processed with an inverse trigonometric function by the micro control unit, the phase difference between the first harmonic component in the secondary resonant voltage and the first harmonic component in the secondary resonant current is obtained, wherein after any low-frequency AC component of the second harmonic component in the secondary resonant voltage and any low-frequency AC component of the second harmonic component in the secondary resonant current at the corresponding time point within the setting time period are processed with an inverse trigonometric function by the micro control unit, the phase difference between the second harmonic component in the secondary resonant voltage and the second harmonic component in the secondary resonant current is obtained.

18. The mutual inductance calculation device according to claim 13, wherein the frequency of the first harmonic component in the primary resonant current, the frequency of the first harmonic component in the secondary resonant current and the frequency of the first harmonic component in the secondary resonant voltage are identical, and the frequency of the second harmonic component in the primary resonant current, the frequency of the second harmonic component in the secondary resonant current and the frequency of the second harmonic component in the secondary resonant voltage are identical, wherein the first harmonic component and the second harmonic component are harmonic components below a fifth-order frequency.

19. The mutual inductance calculation device according to claim 18, wherein the first harmonic component is a fundamental component, and the second harmonic component is a third harmonic component.

20. The mutual inductance calculation device according to claim 14, wherein the analog switch receives a first carrier signal p₁(t), a second carrier signal p₂(t) and a modulation wave signal s(t), wherein the first carrier signal p₁(t) and the second carrier signal p₂(t) are square wave signals, and a phase difference between the first carrier signal p₁(t) and the second carrier signal p₂(t) is 90°, wherein after the analog switch multiplies the modulation wave signal s(t) with the first carrier signal p₁(t) and multiplies the modulation wave signal s(t) with the second carrier signal p₂(t), following formulas are obtained:
$$s ( t ) * {p}_{1} ( t ) = A sin ( ω t + φ ) * {\sum }_{k = 1}^{∞} {B}_{k} sin ( k ω t ) \qquad ( 1 )$$
$$s ( t ) * {p}_{2} ( t ) = A sin ( ω t + φ ) * {\sum }_{k = 1}^{∞} {B}_{k} cos ( k ω t ) \qquad ( 2 )$$
$$s ( t ) = A sin ( ω t + φ ) \qquad ( 3 )$$
$${p}_{1} ( t ) = {\sum }_{k = 1}^{∞} {B}_{k} sin ( k ω t ) \qquad ( 4 )$$
$${p}_{2} ( t ) = {\sum }_{k = 1}^{∞} {B}_{k} cos ( k ω t ) \qquad ( 5 )$$
wherein the modulation wave signal s(t) represents any one of the first harmonic component and the second harmonic component in each of the primary resonant current, the secondary resonant current and the secondary resonant voltage, A is an amplitude of the modulation wave signal s(t), ω is an angular frequency of the modulation wave signal s(t), q is a phase of the modulation wave signal s(t), and Bk represents an amplitude of the first carrier signal p₁(t) and an amplitude of the second carrier signal p₂(t), wherein k is an odd number and represents a frequency of the first carrier signal p₁(t) and a frequency of the second carrier signal p₂(t).

21. The mutual inductance calculation device according to claim 20, wherein the second filtering circuit filters multiplication results of the first carrier signal and the first harmonic component and the second harmonic component in each of the primary resonant current, the secondary resonant current and the secondary resonant voltage respectively, so that a first DC component of the first harmonic component and a first DC component of the second harmonic component in each of the primary resonant current, the secondary resonant current and the secondary resonant voltage are obtained, wherein the first DC component is expressed as:
$$\frac{A {B}_{1} cos ( φ )}{2}$$
wherein B₁ is a value where k is equal to 1,
wherein the second filtering circuit filters multiplication results of the second carrier signal and the first harmonic component and the second harmonic component in each of the primary resonant current, the secondary resonant current and the secondary resonant voltage respectively, so that a second DC component of the first harmonic component and a second DC component of the second harmonic component in each of the primary resonant current, the secondary resonant current and the secondary resonant voltage are obtained, wherein second DC component is expressed as:
$$\frac{A {B}_{1} sin ( ϕ )}{2}$$

22. The mutual inductance calculation device according to claim 21, wherein the amplitude and the phase of the first harmonic component in each of the primary resonant current, the secondary resonant current and the secondary resonant voltage and the amplitude and the phase of the second harmonic component in each of the primary resonant current, the secondary resonant current and the secondary resonant voltage are calculated according to following formulas:
$$\{ \begin{matrix}{C}_{1} = \frac{A {B}_{1} s in ( φ )}{2} \\ {C}_{2} = \frac{A {B}_{1} cos ( φ )}{2}\end{matrix} \qquad ( 6 )$$
$$φ = arctan \frac{{C}_{1}}{{C}_{2}} \qquad ( 7 )$$
$$A = \frac{2 {C}_{1}}{{B}_{1} s in ( φ )} \qquad ( 8 )$$
wherein C₁ is the first DC component of any one of the first harmonic component and the second harmonic component in each of the primary resonant current, the secondary resonant current and the secondary resonant voltage, C₂ corresponds to C₁ and is the second DC component of any one of the first harmonic component and the second harmonic component in each of the primary resonant current, the secondary resonant current and the secondary resonant voltage, φ corresponds to C₁ and C₂ and is the phase of any one of the first harmonic component and the second harmonic component in each of the primary resonant current, the secondary resonant current and the secondary resonant voltage, and A corresponds to C₁ and C₂ and is the amplitude of any one of the first harmonic component and the second harmonic component in each of the primary resonant current, the secondary resonant current and the secondary resonant voltage.

23. The mutual inductance calculation device according to claim 14, wherein the mutual inductance calculation device further includes a differential amplifier and an ADC conversion circuit, wherein amplitudes of the two DC components of the first harmonic component in each of the primary resonant current, the secondary resonant current and the secondary resonant voltage from the second filtering circuit and amplitudes of the two DC components of the second harmonic component in each of the primary resonant current, the secondary resonant current and the secondary resonant voltage from the second filtering circuit are adjusted by the differential amplifier, wherein the adjusted amplitudes of the two DC components of the first harmonic component in each of the primary resonant current, the secondary resonant current and the secondary resonant voltage and the adjusted amplitudes of the two DC components of the second harmonic component in each of the primary resonant current, the secondary resonant current and the secondary resonant voltage are subjected to an analog/digital conversion, and a conversion result of the analog/digital conversion is provided to the micro control unit.

24. The mutual inductance calculation device according to claim 13, wherein the mutual inductance parameter is calculated according to following formulas:
$${ω}_{i} M \vert {I}_{S ι}^{.} \vert = \sqrt{{( ( {ω}_{i} {L}_{S} - \frac{1}{{ω}_{i} {C}_{S}} ) \vert {I}_{S ι}^{.} \vert - \vert {U}_{S ι}^{.} \vert sin {θ}_{i} )}^{2} + {( \vert {U}_{S ι}^{.} \vert cos {θ}_{i} )}^{2}} \qquad ( 9 )$$
$${θ}_{i} = {φ}_{{U}_{S i}} - {φ}_{{I}_{S i}} \qquad ( 10 )$$
wherein \dot{U}_{Sι} is an i-th harmonic component in the secondary resonant voltage, L_{S} is a self-inductance of a secondary winding of the secondary circuit, C_{S} is a capacitance of a secondary compensation capacitor of the secondary circuit,
$${\dot{I}}_{S ι}$$
is an i-th harmonic component in the secondary resonant current, M is the mutual inductance parameter, ωᵢ is the angular frequency at the i-th harmonic component,
$${\dot{I}}_{P ι}$$
is an i-th harmonic component in the primary resonant current, θᵢ is a phase difference between the i-th harmonic component in the secondary resonant voltage and the i-th harmonic component in the secondary resonant current, φ_{U}_{_{Si}} is a phase of the i-th harmonic component in the secondary resonant voltage, and φ_{I}_{_{Si}} is a phase of the i-th harmonic component in the secondary resonant current, wherein if i=1, the i-th harmonic component is the first harmonic component, wherein if i=2, the i-th harmonic component is the second harmonic component.
